(19) United States
(12) Patent Application Publication
(10) Pub. No.: US 2010/0242272 A1
(43) Pub. Date: Sep. 30, 2010

(54) Method of manufacturing printed circuit board

(75) Inventors: Moon-Il Kim, Suwon-si (KR); Young-Do Kweon, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/801,337

(22) Filed: Jun. 3, 2010

Related U.S. Application Data
(62) Division of application No. 12/007,688, filed on Jan. 14, 2008.

(30) Foreign Application Priority Data
Sep. 18, 2007 (KR) 10-2007-0094923

(51) Int. Cl. H05K 3/30

(52) U.S. Cl. 29/832

(57) ABSTRACT

A method of manufacturing a printed circuit board (PCB) having embedded components. The method includes: forming a cavity in one side of a dielectric substrate; inserting a first component in the cavity such that an electrode thereof faces the one side of the dielectric substrate; mounting a second component on one side of the first component such that an electrode thereof faces the same direction as the electrode of the first component; forming a first dielectric layer on one side of the dielectric substrate such that the first dielectric layer covers the second component; and forming a second dielectric layer on the other side of the dielectric substrate such that the second dielectric layer covers the first component.

### CROSS-REFERENCE TO RELATED APPLICATIONS

This application is a U.S. divisional application filed under 35 USC 1.53(b) claiming priority benefit of U.S. Ser. No. 12/007,688 filed in the United States on Jan. 14, 2008, which claims earlier priority benefit to Korean Patent Application No. 10-2007-0094923 filed with the Korean Intellectual Property Office on Sep. 18, 2007, the disclosures of which are incorporated herein by reference.

### BACKGROUND

1. Field

The present invention relates to a PCB (printed circuit board) having embedded components and a method for manufacturing the PCB.

2. Description of the Related Art

Recently, the development of the component-embedded PCB is gaining attention as the next generation technology for multi-functional miniature packages. The component-embedded PCB provides an aspect of high performance, as well as the merits of multi-functionality and miniature size, because it can not only minimize circuit intervals at high frequencies of over 100 MHz, but also improve the reliability of connections that use wire bonding or solder balls in a FCA (flip chip assembly) or a BGA (ball grid array).

However, for the component-embedded PCB according to prior art, when the manufacture involves embedding one component in the dielectric substrate, it is difficult to improve the level of integration, whereas when the manufacture involves embedding two components in the dielectric substrate symmetrically, the method is difficult to apply to cases where the two components have different thicknesses, such as DRAM/NAND flash, etc., used in a MCP (multi chip package) module, and the symmetrical structure leads to exceedingly delayed production speeds.

Accordingly, there is a demand for a PCB having embedded components and a method for manufacturing the PCB, in which the speed of production can be increased, even with multiple components embedded that have different thicknesses, so as to increase the efficiency of production.

### SUMMARY

An aspect of the invention is to provide a PCB having embedded components and a method for manufacturing thereof, in which multiple components having different thicknesses can be mounted sequentially or collectively, and with which vias can be formed more easily.

One aspect of the invention provides a PCB (printed circuit board) having embedded components that includes a dielectric substrate having a cavity formed in one side, a first component inserted in the cavity such that an electrode of the first component faces the one side of the dielectric substrate, a second component mounted on one side of the first component such that an electrode of the second component faces the same direction as the electrode of the first component, a first dielectric layer formed on one side of the dielectric substrate such that the first dielectric layer covers the second component, and a second dielectric layer formed on the other side of the dielectric substrate such that the second dielectric layer covers the first component.

The PCB may further include a first metal post that is formed on an electrode of the first component and connected electrically with the first component, and a second metal post that is formed on electrode of the second component and connected electrically with the second component.

The distance from one side of the first dielectric layer to one end of the first metal post and the distance from one side of the first dielectric to one end of the second metal post may be the same.

The PCB may further include vias that are formed in one side of the first dielectric layer and connected electrically to the first metal post and the second metal post, respectively.

The width of the first component may be greater than the width of the second component.

The thickness of the first component may be greater than the thickness of the second component.

The PCB may further include an adhesive layer placed between the first component and the second component.

The PCB may further include a first circuit pattern formed on one side or both sides of the dielectric substrate.

The PCB may further include a second circuit pattern formed on at least one of one side of the first dielectric layer and one side of second dielectric layer

The PCB may further include a redistribution layer interposed between the first component and the second component that is electrically connected with an electrode of the first component.

Another aspect of the invention provides a method for manufacturing a printed circuit board having embedded components that includes: forming a cavity in one side of a dielectric substrate, inserting a first component in the cavity such that an electrode of the first component faces the one side of the dielectric substrate, mounting a second component on one side of the first component such that an electrode of the second component faces the same direction as the electrode of the first component, forming a first dielectric layer on one side of the dielectric substrate such that the first dielectric layer covers the second component, and forming a second dielectric layer on the other side of the dielectric substrate such that the second dielectric layer covers the first component.

The method may further include forming a first circuit pattern on at least one side of the dielectric substrate, before forming the first dielectric layer and the second dielectric layer.

The method may further include applying a securing tape on the other side of the dielectric substrate so as to secure the first component in the cavity, before inserting the first component, and may include removing the securing tape, after forming the first dielectric layer.

The method may further include forming a first metal post on an electrode of the first component such that the first metal post is connected electrically with the first component, and forming a second metal post on an electrode of the second component such that the second metal post is connected electrically with the second component, before forming the first dielectric layer.

The method may further include forming vias on one side of the first dielectric layer such that the vias are electrically connected to the first metal post and the second metal post respectively, after forming the first dielectric layer.

The method may further include forming an adhesive layer on one side of the first component, before mounting the second component.

The method may further include forming a second circuit pattern on at least one of one side of the first dielectric layer and one side of the second dielectric layer, after forming the first dielectric layer and forming the second dielectric layer.

The width of the first component may be greater than the width of the second component.

The thickness of the first component may be greater than the thickness of the second component.

The mounting of the second component may be performed before inserting the first component.

The forming of the second dielectric layer may be performed before inserting the first component.

The method may further include forming a redistribution layer on one side of the first component such that the redistribution layer is connected electrically with an electrode of the first component, before mounting the second component.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view illustrating a first disclosed embodiment of a PCB having embedded components according to an aspect of the present invention.

FIG. 2 is a cross-sectional view illustrating a second disclosed embodiment of a PCB having embedded components according to an aspect of the present invention.

FIG. 3 is a flowchart illustrating a first disclosed embodiment of a method for manufacturing a PCB having embedded components according to another aspect of the present invention.

FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, and FIG. 17 are cross-sectional views illustrating each process in the first disclosed embodiment of a method for manufacturing a PCB having embedded components according to another aspect of the present invention.

FIG. 18 is a flowchart illustrating a second disclosed embodiment of a method for manufacturing a PCB having embedded components according to another aspect of the present invention.

FIG. 19, FIG. 20, FIG. 21, FIG. 22, FIG. 23, FIG. 24, FIG. 25, FIG. 26, FIG. 27, FIG. 28, FIG. 29, FIG. 30, FIG. 31, FIG. 32, and FIG. 33 are cross-sectional views illustrating each process in the second disclosed embodiment of a method for manufacturing a PCB having embedded components according to another aspect of the present invention.

### DETAILED DESCRIPTION OF EMBODIMENTS

The PCB (printed circuit board) having embedded components and method for manufacturing thereof according to certain embodiments of the invention will be described below in more detail with reference to the accompanying drawings, in which those elements are rendered the same reference numeral that are the same or are in correspondence, regardless of the figure number, and redundant explanations are omitted.

Also, terms such as “first,” “second,” etc., are used only to distinguish elements that are the same or are in correspondence to one another, and the same or corresponding elements are not to be limited by the above terms.

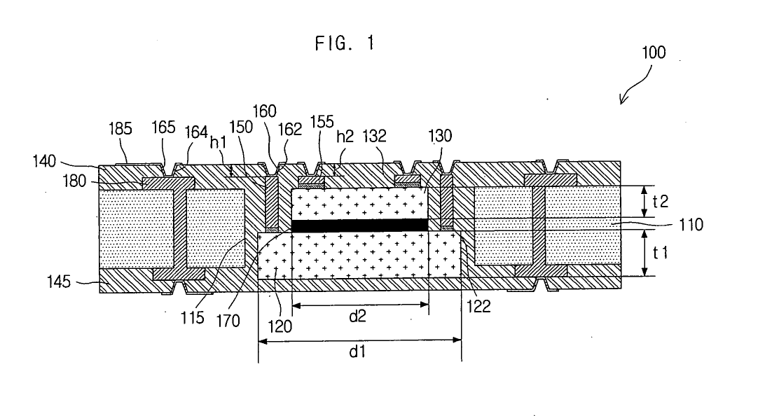

FIG. 1 is a cross-sectional view illustrating a first disclosed embodiment of a PCB having embedded components according to an aspect of the present invention. In FIG. 1 are illustrated a component-embedded PCB 100, a dielectric substrate 110, a cavity 115, a first component 120, a second component 130, electrodes 122, 132, a first dielectric layer 140, a second dielectric layer 145, first metal posts 150, second metal posts 155, via holes 162, 164, vias 160, 165, an adhesive layer 170, a first circuit pattern 180, and a second circuit pattern 185.

According to this embodiment, a first component 120 and a second component 130 may be embedded, such that the electrodes 122, 132 of each face the same direction, in a cavity 115 of a dielectric substrate 110. In this way, a component-embedded PCB 100 may be obtained in which multiple components having different thicknesses t1, t2 can be embedded, and in which vias 160 for electrical connection with the exterior can be formed more easily.

On one side of the dielectric substrate 110, a cavity 115 may be formed, in which the first component 120 and second component 130 may be embedded. For example, a dielectric substrate 110 may be a part of a CCL (copper clad laminate) substrate, and thus a first circuit pattern 180 formed on at least one side, that is, on one side, the other side, or both sides, of the dielectric substrate 110, while inside the dielectric substrate 110, interconnections may be formed for electrically connecting either side of the dielectric substrate 110.

The first circuit pattern 180 may be formed by etching the copper layer formed on one side, the other side, or both sides of the dielectric substrate 110, e.g. a part of a CCL substrate.

The first circuit pattern 180 may be formed by first coating etching resist on the copper layer, performing exposure and development according to a photolithography process, and then applying an etchant on portions of the copper layer to remove the portions.

The interconnections may be formed to electrically connect either side of the dielectric substrate 110, in cases where the first circuit pattern 180 is formed on both sides of the dielectric substrate 110. Conductive materials such as copper, for example, may be used for forming the interconnections.

The interconnection can be formed by first perforating penetration holes in the dielectric substrate 110, for example, by drilling, performing a post-treatment process such as deburring or desmearing if required, and then filling conductive material in the penetration holes, for example, by copper plating, panel plating, or pattern plating, etc.

The cavity 115 may be formed in one side of the dielectric substrate 110. While this embodiment presents as an example the case where the dielectric substrate 110 is perforated completely from one side of the dielectric substrate 110 to the other, it is to be appreciated that certain embodiments of the invention may include those cases where a recess is formed in one side of the dielectric substrate 110 without having the dielectric substrate 110 penetrated.

The cavity 115 may be manufactured in a position corresponding to the position where the first component 120 and second component 130 are to be inserted, and may be formed in one side of the dielectric substrate 110 by a method such as laser cutting, routing, and punching, etc.

The first component 120 may be inserted in the cavity 115 such that the electrodes 122 face one side of the dielectric substrate 110. For example, the first component 120 may be a chip such as DRAM or NAND flash, etc.

Before inserting the first component 120, a securing tape may be applied on the other side of the dielectric substrate 110 to secure the first component 120 in the cavity 115. After mounting the second component 130 on one side of the first component 120 and forming a first dielectric layer 140 on the dielectric substrate 110 to cover the second component 130, the securing tape may be removed, and the second dielectric layer 145 may be formed on the other side of the dielectric substrate 110.

The securing tape may be a heat-resisting tape, which does not leave any residue after it is removed. A tape made of a PI (polyimide) material, for example, may be used for the securing tape.

Besides the method of securing the first component 120 by using the securing tape, a method may be used of forming the second dielectric layer 145 on the other side of the dielectric substrate 110 before the first component 120 is inserted. In this way, the component-embedded PCB 100 may be manufactured efficiently without the use of any separate securing means.

First metal posts 150 may be formed on the electrodes 122 of the first component 120 so that they may be connected electrically with the first component 120. The first component 120 may then be connected electrically with the exterior by perforating via holes 162 in the first dielectric layer 140 and forming vias 160.

The first metal posts 150 may be manufactured by forming a plating resist layer, which has penetration holes formed in positions corresponding to the electrodes 122 of the first component 120, on one side of the first component 120, and afterwards filling in conductive material inside the penetration holes, for example by a process of plating.

Each end of the first metal posts 150 and the second metal posts 155 can be positioned at a corresponding distance h1, h2 from one side of the first dielectric layer 140. Thus, in forming the vias 160 in one side of the first dielectric layer 140 for electrical connection with the exterior, the vias 160 may be formed more easily by processing the via holes 162 to the corresponding depths, when forming the via holes by laser drilling, etc.

The second component 130 may be mounted on one side of the first component 120 such that the electrodes 132 face the same direction as the electrodes 122 of the first component 120, while an adhesive layer 170 may be interposed on one side of the first component 120. The second component 130 may be a chip such as DRAM or NAND flash etc., but the width d1 and thickness t1 of a first component 120 may be different from the width d2 and thickness t2 of the second component 130. This matter will be discussed later in more detail.

The adhesive layer 170 may be interposed between the first component 120 and the second component 130, where a DAF (die attach film), NCA (non-conductive adhesive), or epoxy, etc., may be used for the adhesive layer 170. First, the adhesive layer 170 may be applied on one side of the first component 120, and then the second component 130 may be mounted on the adhesive layer 170, whereby the second component 130 may be secured without moving when forming the first dielectric layer 140.

The adhesive layer 170 may be placed between the first component 120 and the second component 130 after the first component 120 is inserted in the cavity 115 of the dielectric substrate 110, after which the second component 130 may be mounted sequentially on one side of the first component 120.

Alternately, the adhesive layer 170 may be placed between the first component 120 and the second component 130 before the first component 120 is inserted in the cavity 115 of the dielectric substrate 110, after which the second component 130 may be mounted on one side of the first component, and then the first component 120 and second component 130 may be inserted in the cavity 115 of the dielectric substrate 110 collectively. As such, a component-embedded PCB 100 may be manufactured more easily, as the processes can be employed with high flexibility.

As such, by having the first component 120 and second component 130 mounted such that their electrodes 122, 132 face the same direction, the first component 120 and second component 130 may be inserted in the cavity 115 of the dielectric substrate 110 either one after the other or both together, in cases where it would be difficult to form a symmetrical structure due to differing thicknesses t1, t2 of the components. Thus, the component-embedded PCB 100 may be manufactured more easily, and vias 160 for electrically connecting the electrodes 122, 132 with the exterior may be formed more easily as well.

The second metal posts 155 may be formed on the electrodes 132 of the second component 130 such that they may be electrically connected with the second component 130. The second component 130 may then be connected electrically with the exterior by perforating via holes 162 in the first dielectric layer 140 and forming vias 160.

The second metal posts 155, similar to the first metal posts 150, may be manufactured by forming a plating resist layer, which has penetration holes formed in positions corresponding to the electrodes 132 of the second component 130, on one side of the second component 130, and afterwards filling in conductive material inside the penetration holes, for example by a process of plating.

The first metal posts 150 and second metal posts 155 may be formed separately before the second component 130 is mounted on one side of the first component 120, or may be formed simultaneously after the second component 130 is mounted on one side of the first component 120.

Each end of the first metal posts 150 and the second metal posts 155 can be positioned at corresponding distances h1, h2 from one side of the first dielectric layer 140. Thus, in forming the vias 160 in one side of the first dielectric layer 140 for electrical connection with the exterior, the vias 160 may be formed more easily by processing the via holes 162 to the corresponding depths, when forming the via holes by laser drilling, etc.

The width d1 of the first component 120 may be greater than the width d2 of the second component 130, in which case there may be no interference position-wise between the electrodes 122 of the first component 120 and the electrodes 132 of the second component 130. As such, the first metal posts 150 and second metal posts 155 may each be formed more easily to face one side of the first dielectric layer 140.

Also, the thickness t1 of the first component 120 may be greater than the thickness t2 of the second component 130, in which case the first metal posts 150 formed on the electrodes 122 of the first component 120 may not necessarily require a long length. As such, the component-embedded PCB 100 may be manufactured with greater efficiency.

The first dielectric layer 140 may be formed on one side of the dielectric substrate 110 that covers the second component 130, and accordingly, the first metal posts 150 and second metal posts 155 may be buried in the first dielectric layer 140.

Also, the second dielectric layer 145 may be formed on the other side of the dielectric substrate 110 that covers the first component 120, and consequently, a PCB may be manufactured that has the first component 120 and second component 130 embedded.

Vias 160 may be formed in one side of a first dielectric layer 140 that are electrically connected to the first metal posts 150 and second metal posts 155 respectively, and accordingly, the first component 120 and second component 130 may be connected electrically with the exterior.

The vias 160 may be formed by perforating via holes 162 in positions corresponding to the first metal posts 150 and second metal posts 155 by a method such as laser drilling and lithography, etc., and plating one side of the first dielectric layer 140 with a conductive material such as copper, to fill the via holes 162.

A second circuit pattern 185 may be formed on at least one of one side of the first dielectric layer 140 and one side of the second dielectric layer 145, in other words, on one side of the first dielectric layer 140, on one side of the second dielectric layer 145, or on one side of each of the first dielectric layer 140 and the second dielectric layer 145. The second circuit pattern 185 may be connected electrically with the first circuit pattern 180 by way of the vias 165 filled in the via holes 164.

The second circuit pattern 185 may be formed by etching a plating layer formed on one side of the first dielectric layer 140 and on one side of the second dielectric layer 145 for forming the vias 160. That is, the second circuit pattern 185 may be formed by coating etching resist on a copper layer, performing exposure and development according to a photolithography process, and applying etchant on portions of the copper layer to remove the portions.

According to this embodiment, the first component 120 and second component 130 may be inserted such that the electrodes 122, 132 of the first component 120 and second component 130 face the same direction, so that consequently, the first component 120 and second component 130 may be electrically connected with the exterior more easily. In addition, as the distance h1, h2 from each of the first metal posts 150 and second metal posts 155 to one side of the first dielectric layer 140 may be in correspondence, the via holes 162 may also be formed more easily.

Furthermore, the width d1 and thickness t1 of the first component 120 may be greater than the width d2 and thickness t2 of the second component 130, so that there may be no interference between each electrode 122, 132 in terms of position, and the first metal posts 150 and second metal posts 155 may be formed more easily.

Next, a description will be provided with regards a second disclosed embodiment of a component-embedded PCB according to an aspect of the present invention, which has a redistribution layer formed between the first component and the second component.

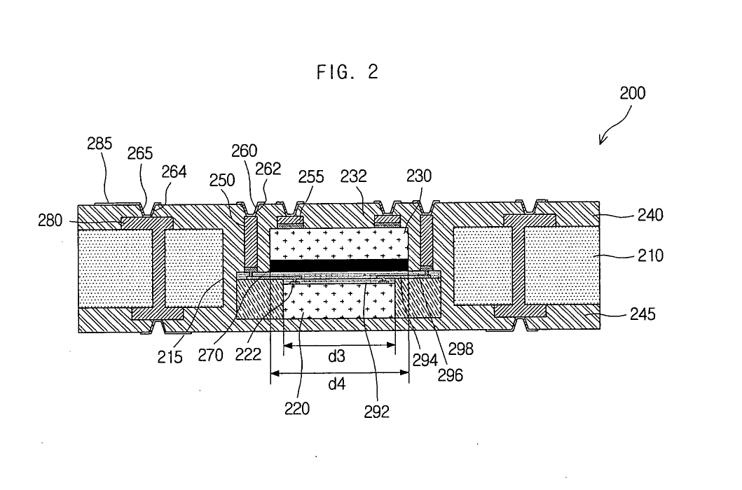

FIG. 2 is a cross-sectional view illustrating a second disclosed embodiment of a PCB having embedded components according to an aspect of the present invention. In FIG. 2 are illustrated a component-embedded PCB 200, a dielectric substrate 210, a cavity 215, a first component 220, a second component 230, electrodes 222, 232, a first dielectric layer 240, a second dielectric layer 245, first metal posts 250, second metal posts 255, via holes 262, 264, vias 260, 265, an adhesive layer 270, a first circuit pattern 280, a second circuit pattern 285, a first protection layer 292, a redistribution layer 294, a second protection layer 296, and bumps 298.

According to this embodiment, a component-embedded PCB 200 is presented, in which a redistribution layer 294, a first protection layer 292, a second protection layer 296 and bumps 298 may be interposed between the first component 220 and the second component 230, for an increased degree of freedom in designing the component-embedded PCB 200.

In this embodiment, the dielectric substrate 210, cavity 215, first component 220, second component 230, electrodes 222, 232, first dielectric layer 240, second dielectric layer 245, first metal posts 250, second metal posts 255, via holes 262, 264, vias 260, 265, adhesive layer 270, first circuit pattern 280, and second circuit pattern 285 are the same as or are in correspondence with the elements described above with reference to the first disclosed embodiment of a component-embedded PCB according to an aspect of the present invention. Thus, redundant explanations will be omitted, and the following will focus on descriptions on the redistribution layer 294, first protection layer 292, second protection layer 296, and bumps 298, as well as the widths d3, d4 of the first component 220 and second component 230, which form the differences of this embodiment from the first disclosed embodiment of the component-embedded PCB.

A first protection layer 292 may be formed on one side of the first component 220, with portions of the electrodes 222 of the first component 220 exposed. The first protection layer 292 may be formed by a process of exposure and development according to photolithography, and the first protection layer 292 may serve as the base of the redistribution layer 294.

The redistribution layer 294 may be interposed between the first component 220 and the second component 230 and may be connected electrically with an electrode 222 of the first component 220, so that the first metal posts 250 and second metal posts 255 may be formed without interference position-wise for the respective electrodes 222, 232, even when the width d3 of the first component 220 is smaller than the width d4 of the second component 230.

A molding material may be formed on the side of the first component 220 that may be used as a base of the redistribution layer 294. The redistribution layer 294, electrically connected with an electrode 222 of the first component 220, may then be formed on one side of the molding material and the first protection layer 292.

The redistribution layer 294 may be formed by forming a plating layer on one side of the molding material and the first protection layer 292, for example, by plating, and forming an etching resist layer on which a pattern may be formed by a method of photolithography, and finally selectively etching the plating layer.

A second protection layer 296 may be formed on one side of the first protection layer 292. The second protection layer 296 may expose portions of the redistribution layer 294, and may cover the remaining portions. Similar to the first protection layer 292, the second protection layer 296 may be formed by photolithography.

A bump 298 may be formed on a portion of the redistribution layer 294 exposed so that the first metal post 250 may be formed easily, and similar to the redistribution layer 294, may be formed by forming a plating layer, for example, by plating, and forming an etching resist layer on which a pattern may be formed by a method of photolithography, and finally selectively etching the plating layer.

According to this embodiment, the degree of freedom is increased in designing a component-embedded PCB 200, as a redistribution layer 294 may be interposed between the first component 220 and second component 230, so that the first metal posts 250 and second metal posts 255 may be formed without being limited by the widths d3, d4 of the first component 220 and second component 230.

Next, a description will be provided with regards a first disclosed embodiment of a method for manufacturing a component-embedded PCB according to another aspect of the present invention.

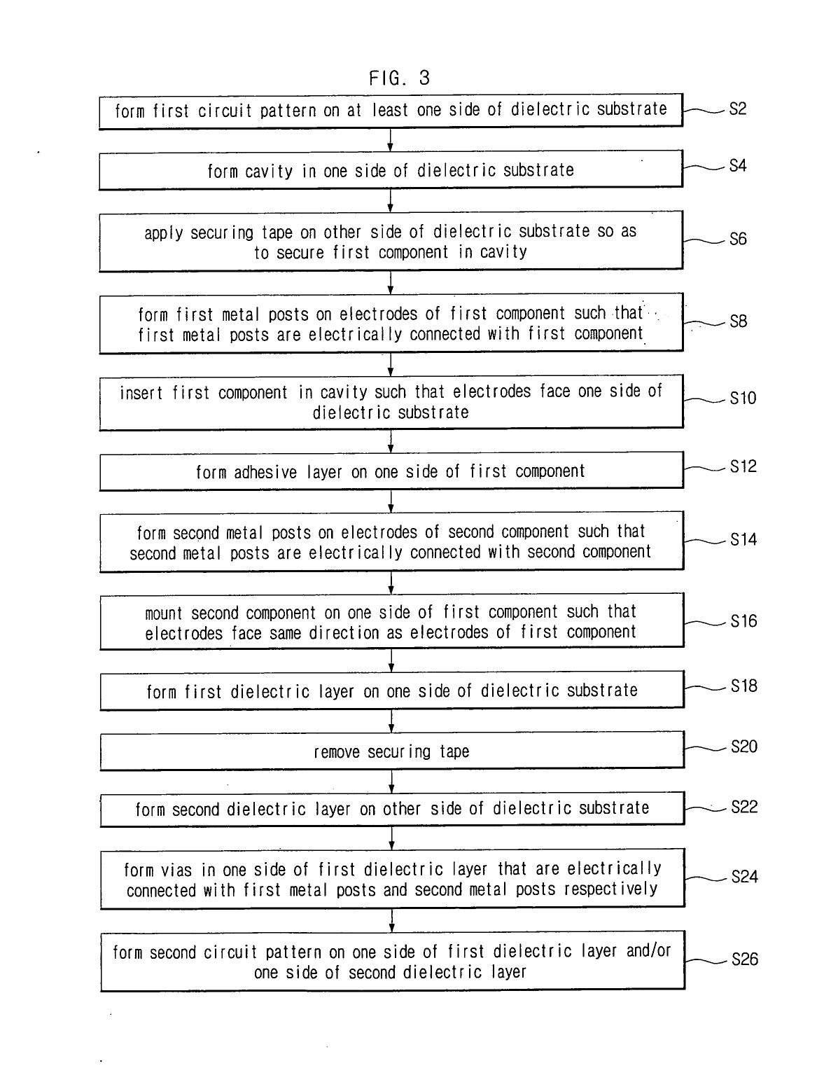

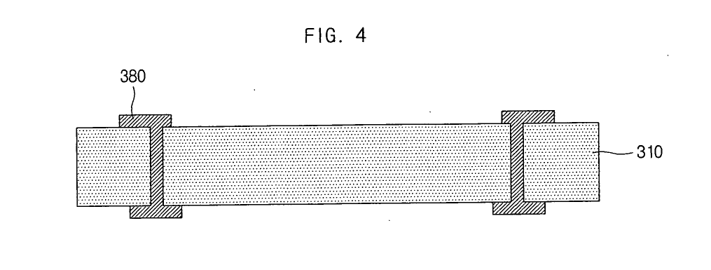

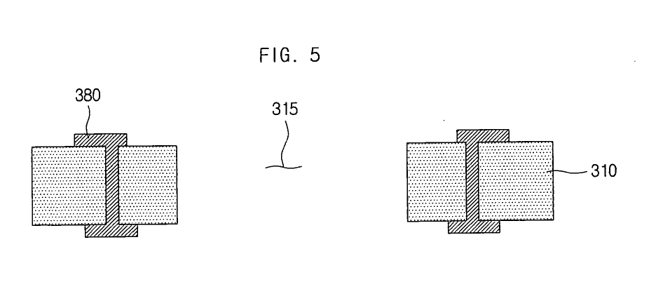

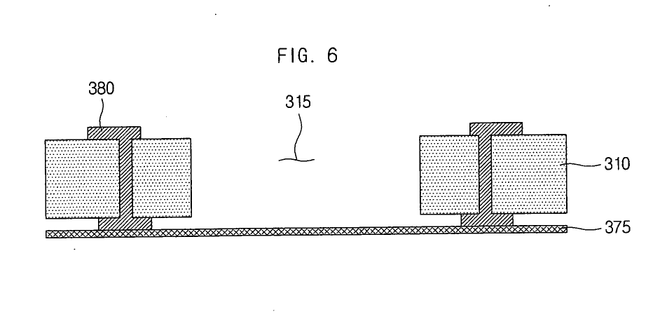

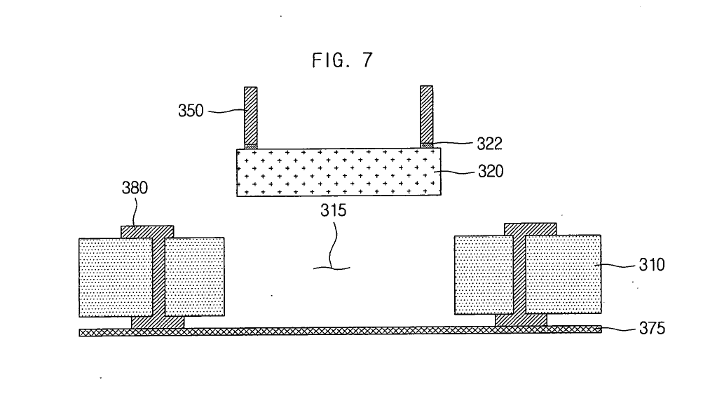

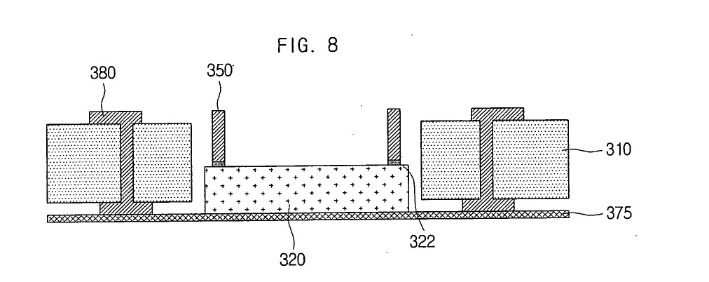

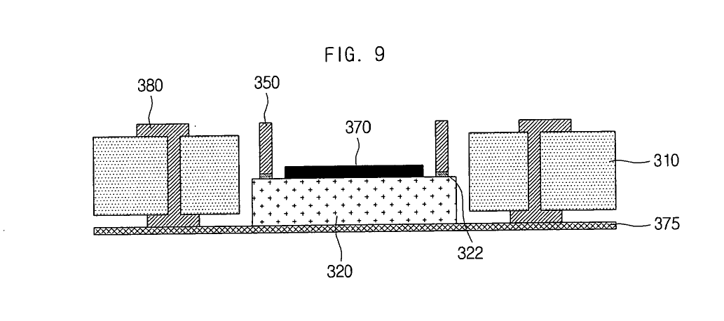

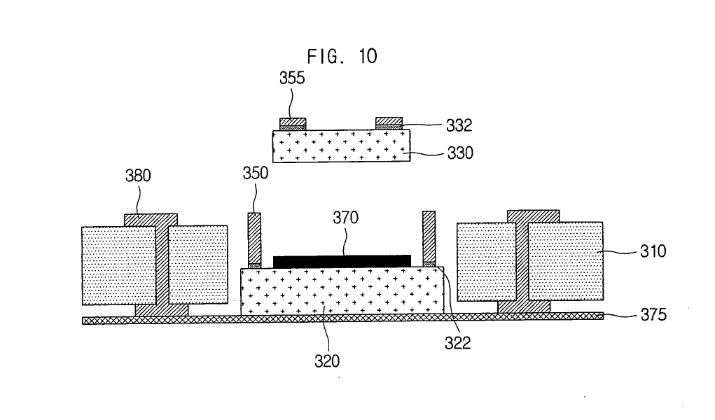

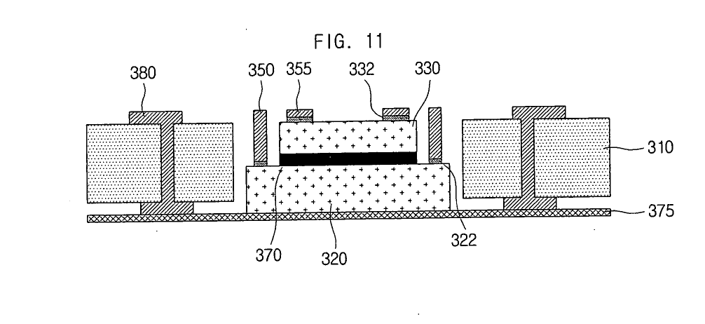

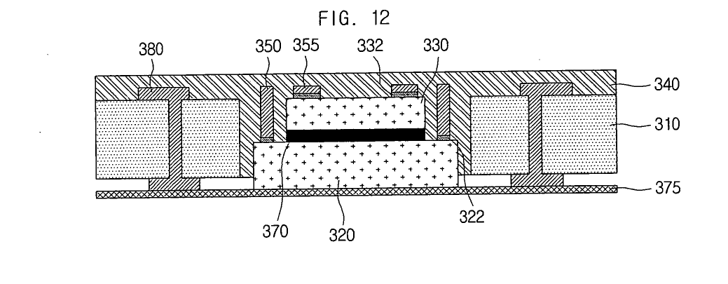

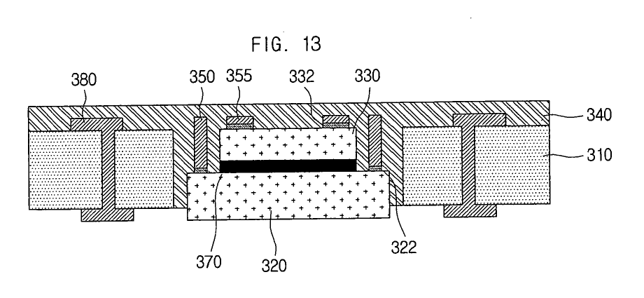

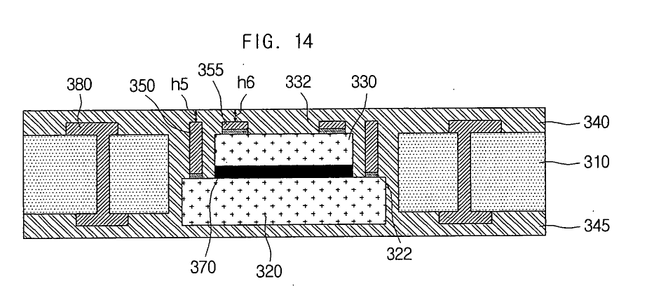

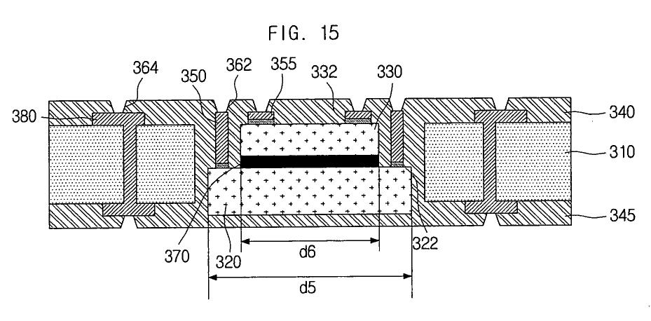

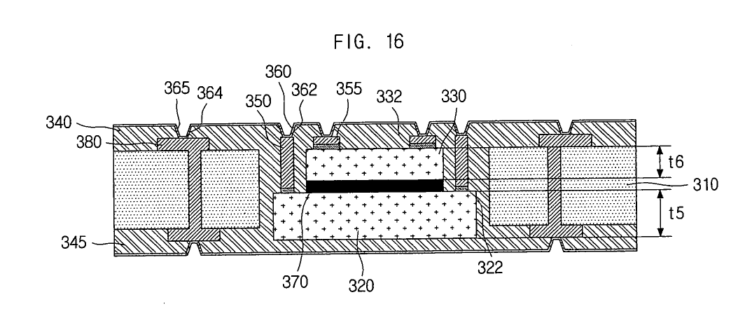

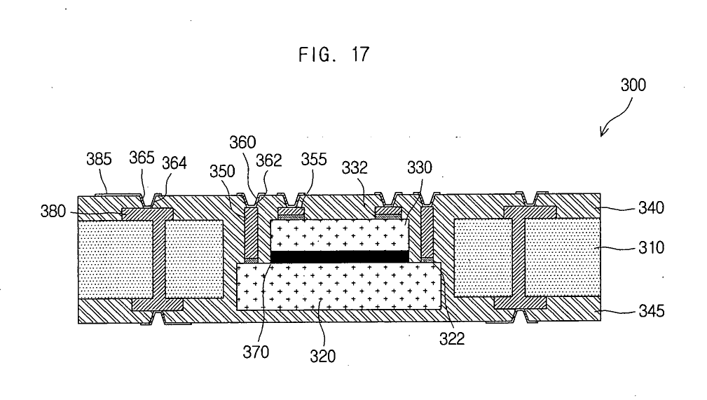

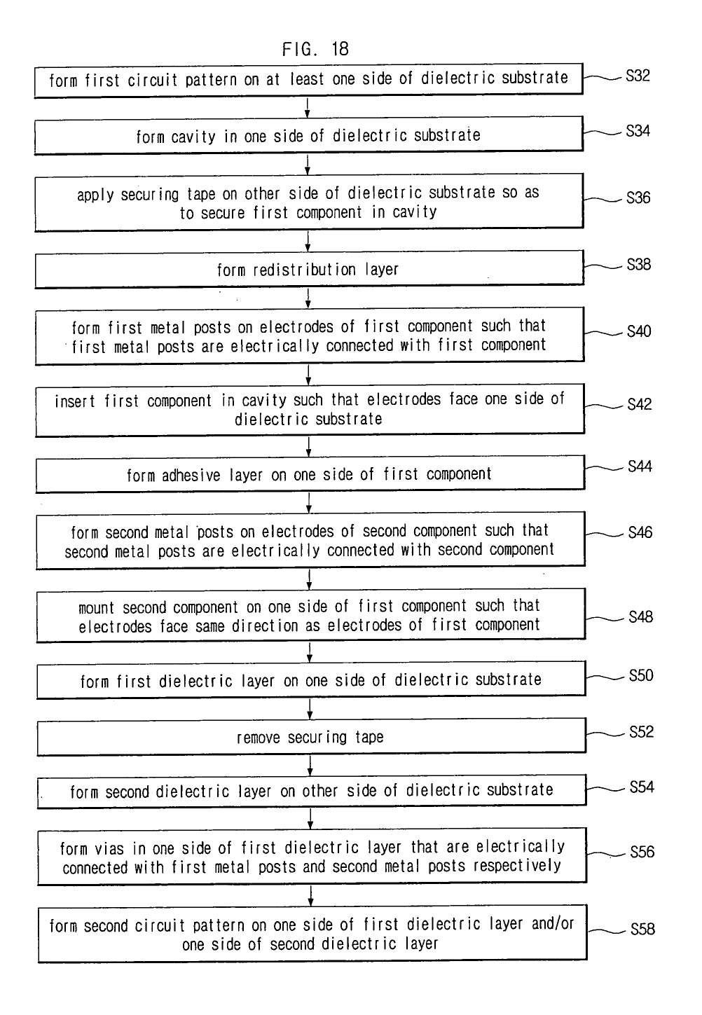

FIG. 3 is a flowchart illustrating a first disclosed embodiment of a method for manufacturing a PCB having embedded components according to another aspect of the present invention, and FIG. 4 to FIG. 17 are cross-sectional views illustrating each process in the first disclosed embodiment of a method for manufacturing a PCB having embedded components according to another aspect of the present invention.

In FIG. 3 to FIG. 17 are illustrated a component-embedded PCB 300, a dielectric substrate 310, a cavity 315, a first component 320, a second component 330, electrodes 322, 332, a first dielectric layer 340, a second dielectric layer 345, first metal posts 350, second metal posts 355, via holes 362, 364, vias 360, 365, an adhesive layer 370, a first circuit pattern 380, a second circuit pattern 385, and a securing tape 375.

According to this embodiment, a method for manufacturing a PCB 300 having embedded components is presented, in which a first component 320 and a second component 330 are embedded in a cavity 315 of a dielectric substrate 310 such that the electrodes 322, 332 of each component face the same direction, whereby the component-embedded PCB 300 may be manufactured more easily in a simple manner.

Operation S2 of FIG. 3 may include forming a first circuit pattern 380 on at least one side of the dielectric substrate 310, where FIG. 4 represents a corresponding process. For example, the dielectric substrate 310 may be a part of a CCL (Copper clad laminate) substrate, and thus a first circuit pattern 380 may be formed by etching the copper layer formed on one side, the other side, or both sides of the dielectric substrate 310.

The first circuit pattern 380 may be formed by coating etching resist on the copper layer, performing exposure and development according to a photo-lithography process, and then applying an etchant on portions of the copper layer to remove the portions.

Interconnections may be formed to electrically connect either side of the dielectric substrate 310, in cases where the first circuit pattern 380 is formed on both sides of the dielectric substrate 310, and conductive materials such as copper, for example, may be used for forming the interconnections.

The interconnection can be formed by first perforating penetration holes in the dielectric substrate 310, for example, by drilling, performing a post-treatment process such as deburring or desmearing if required, and then filling conductive material in the penetration holes, for example, by copper plating, panel plating, or pattern plating, etc.

Operation S4 of FIG. 3 may include forming a cavity 315 in one side of the dielectric substrate 310, where FIG. 5 represents a corresponding process. That is, the cavity 315 may be manufactured in a position corresponding to the position where the first component 320 and the second component 330 are to be inserted, and may be formed in one side of the dielectric substrate 310, for example, by using a method of laser cutting, routing, or punching, etc.

Operation S6 of FIG. 3 may include applying a securing tape 375 on the other side of the dielectric substrate 310 so as to secure the first component 320 in the cavity, where FIG. 6 represents a corresponding process. The securing tape 375 may be a heat-resistant tape which does not leave residue behind when removed, and for example, may be a tape made of a PI (polyimide) material.

While this embodiment presents a method of fixing the first component 120 using a securing tape 375, other methods may be used. For example, the second dielectric layer 345 may be formed on the other side of the dielectric substrate 310 before the first component 320 is inserted, so that the component-embedded PCB 300 may be manufactured efficiently without the use of a special securing means.

Operation S8 of FIG. 3 may include forming first metal posts 350 on the electrodes 322 of the first component 320 so that they may be connected electrically with the first component 320, where FIG. 7 represents a corresponding process. The first metal posts 350 may be manufactured by forming a plating resist layer, which has penetration holes formed in positions corresponding to the electrodes 322 of the first component 320 on one side of the first component 320, and afterwards filling in conductive material inside the penetration holes, for example by a process of plating.

Operation S10 of FIG. 3 may include inserting a first component 320 in the cavity 315 such that the electrodes face one side of the dielectric substrate 310, where FIG. 8 represents a corresponding process. The first component 320 may be inserted in the cavity 315 such that the electrodes 322 face one side of the dielectric substrate 310. For example, the first component 320 may be a chip such as DRAM or NAND flash, etc.

Operation S12 of FIG. 3 may include forming an adhesive layer 370 on one side of the first component 320, where FIG. 9 represents a corresponding process. The adhesive layer 370 may be placed between the first component 320 and the second component 330, where a DAF, NCA, or epoxy, etc., may be used. First, the adhesive layer 370 may be applied on one side of the first component 320, and then the second component 330 may be mounted on the adhesive layer 370, so that the second component 330 may be secured without moving when forming the first dielectric layer 340.

Operation S14 of FIG. 3 may include forming second metal posts 355 on the electrodes 332 of the second component 330 so that they may be connected electrically with the second component 330, where FIG. 10 represents a corresponding process. The second metal posts 355 may be manufactured by forming a plating resist layer, which has penetration holes formed in positions corresponding to the electrodes 332 of the second component 330 on one side of the second component 330, and afterwards filling in conductive material inside the penetration holes, for example by a process of plating.

Here, one end of a first metal post 350 and one end of a second metal post 355 may be positioned at corresponding distances h5, h6 from one side of the first dielectric layer 340. Thus, in forming the vias 360 in one side of the first dielectric layer 340 for electrical connection with the exterior, the vias 360 may be formed more easily by processing the via holes 362 to the corresponding depths, when forming the via holes by laser drilling, etc.

Operation S16 of FIG. 3 may include mounting a second component 330 on one side of the first component 320 such that the electrodes 332 face the same direction as the electrodes 322 of the first component 320, where FIG. 11 represents a corresponding process. The second component 330 may be mounted on one side of the first component 320 such that the electrodes 332 face the same direction as the electrodes 322 of the first component 320, and may have an adhesive layer 370 interposed on one side of the first component 320. The second component 330 may be a chip, such as DRAM or NAND flash, etc.

The width d5 of the first component 320 may be greater than the width d6 of the second component 330, so that there is no interference, in terms of position, between the electrodes 322 of the first component 320 and the electrodes 332 of the second component 330. As such, the first metal posts 350 and second metal posts 355 may be formed more easily, facing one side of the first dielectric layer 340.

Also, the thickness t5 of the first component 320 may be greater than the thickness t6 of the second component 330, so that the first metal posts 350 formed on the electrodes 322 of the first component 320 do not have to be very long. As such, the PCB 300 having embedded components may be manufactured with greater efficiency.

This embodiment presents the case where the second component 330 may be mounted sequentially on one side of the first component 320 with an adhesive layer 370 interposed in-between, after inserting the first component 320 in the cavity 315 of the dielectric substrate 310. However, it is to be appreciated that such cases are included in embodiments of the invention, where the second component 330 is mounted on one side of the first component 320, with an adhesive layer 370 interposed, before the first component 320 is inserted in the cavity 315 of the dielectric substrate 310, and the first component 320 and second component 330 are inserted collectively in the cavity 315 of the dielectric substrate 310. This may allow easier position control in mounting the second component 330, whereby production efficiency can be increased for the component-embedded PCB 300.

Operation S18 of FIG. 3 may include forming a first dielectric layer 340 on one side of the dielectric substrate 310, where FIG. 12 represents a corresponding process. That is, the first dielectric layer 340 may be formed, on one side of the dielectric substrate 310, to cover the second component 330, whereby the first metal posts 350 and second metal posts 355 may be buried in the first dielectric layer 340.

Operation S20 of FIG. 3 may include removing the securing tape 375, where FIG. 13 represents a corresponding process. The securing tape 375 for securing the first component 320 may be removed so that a second dielectric layer 345 may be formed.

Operation S22 of FIG. 3 may include forming a second dielectric layer 345 on the other side of the dielectric substrate 310, where FIG. 14 represents a corresponding process. The second dielectric layer 345 may be formed on the other side of the dielectric substrate 310 to cover the first component 320, which results in the manufacture of a PCB in which the first component 120 and second component 130 are embedded.

Operation S24 of FIG. 3 may include forming vias 360 in one side of the first dielectric layer 340 that are electrically connected to the first metal posts 350 and second metal posts 355 respectively, where FIG. 15 and FIG. 16 represent corresponding processes. First, the vias 360 may be formed by perforating via holes 362 in positions corresponding to the first metal posts 350 and second metal posts 355 by method such as laser drilling or lithography, etc., as shown in FIG. 15, and plating one side of the first dielectric layer 340 with a conductive material such as copper to fill the via holes 362, as shown in FIG. 16.

Also, vias 365 for electrically connecting the first circuit pattern 380 with a second circuit pattern 385 may be formed simultaneously, by forming via holes 364 during the process for forming the vias 360 that are to be connected electrically to the first metal posts 350 and second metal posts 355.

Operation S26 of FIG. 3 may include forming a second circuit pattern 385 on one side of the first dielectric layer 340 and/or one side of the second dielectric layer 345, where FIG. 17 represents a corresponding process. The second circuit pattern 385 may be formed by etching a plating layer formed on one side of the first dielectric layer 340 and on one side of the second dielectric layer 345 for forming the vias 360. That is, the second circuit pattern 385 may be formed by coating etching resist on a copper layer, performing exposure and development according to a photolithography process, and applying etchant on portions of the copper layer to remove the portions.

According to this embodiment, by embedding the first component 320 and the second component 330 in the cavity 315 of the dielectric substrate 310 such that the electrodes 322, 332 of each face the same direction, a multiple number of components may be embedded from one direction, so that a component-embedded PCB 300 may be manufactured with greater efficiency.

Also, as the respective distances h5, h6 from one side of the first dielectric layer 340 to one end of each of the first metal posts 350 and the second metal posts 355 may be in correspondence, the via holes 362 may be formed with greater ease. Furthermore, the width d5 and thickness t5 of the first component 320 may be greater than the second component 330, so that there may be no interference between each electrode 322, 332 in terms of position, and the first metal posts 350 and second metal posts 355 may be formed more easily.

Next, a description will be provided with regards a second disclosed embodiment of a method for manufacturing a component-embedded PCB according to another aspect of the present invention, which has a redistribution layer formed between the first component and the second component.

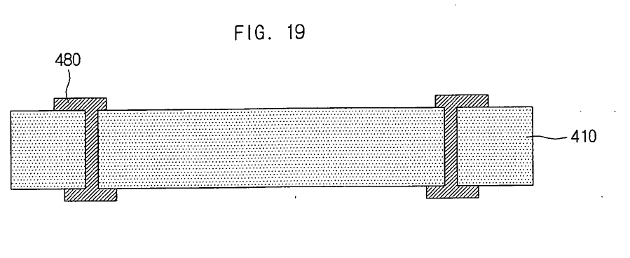

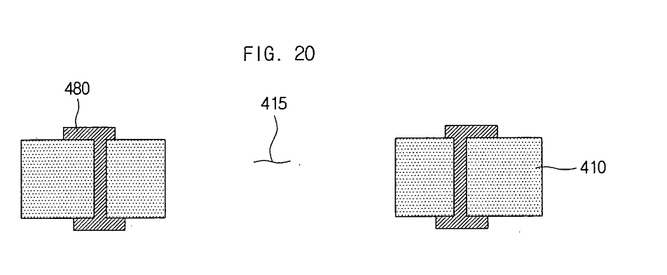

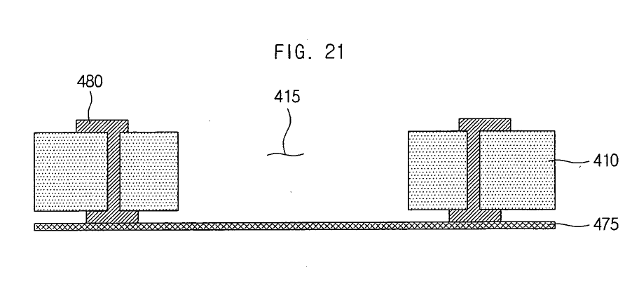

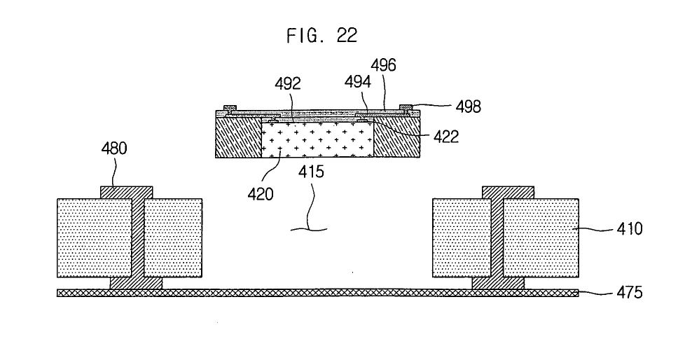

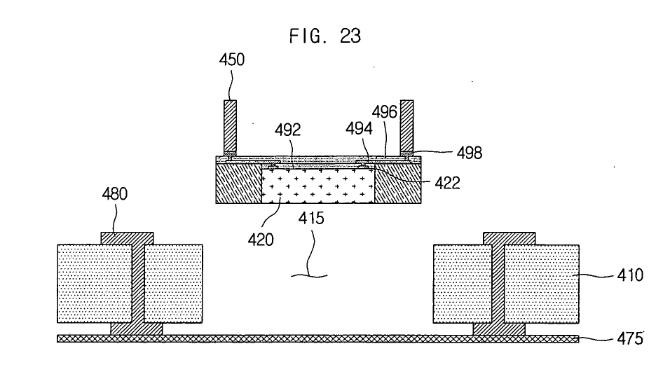

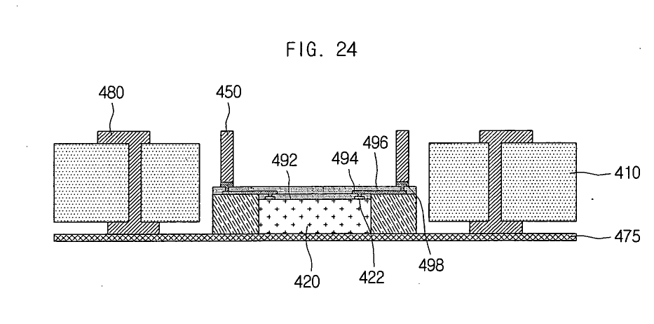

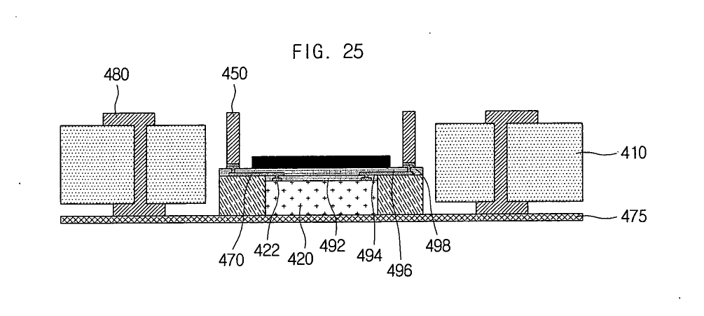

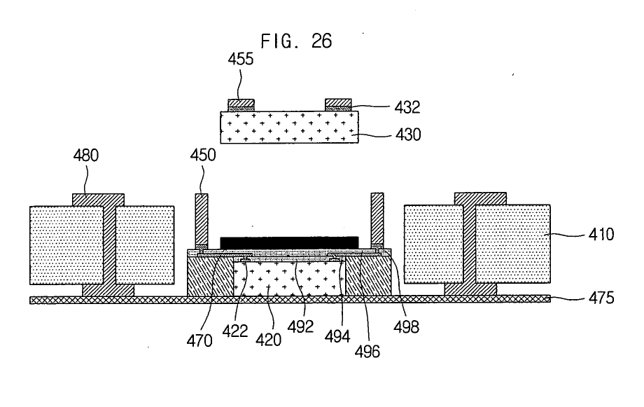

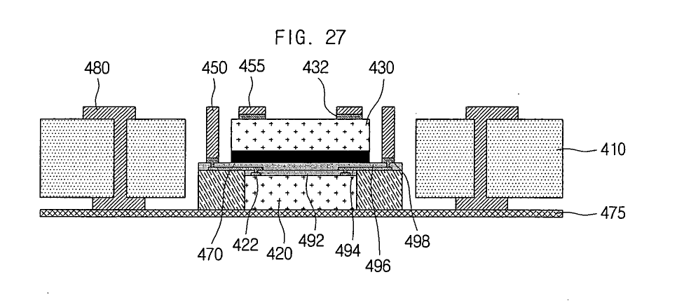

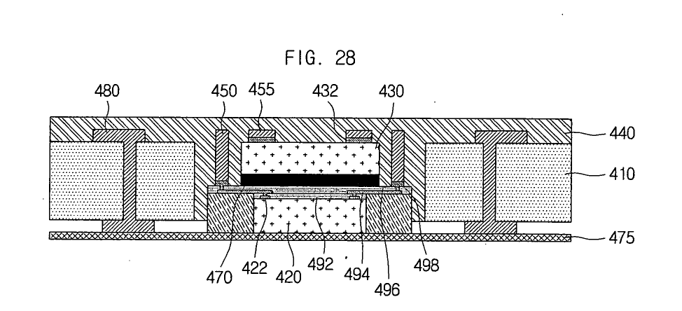

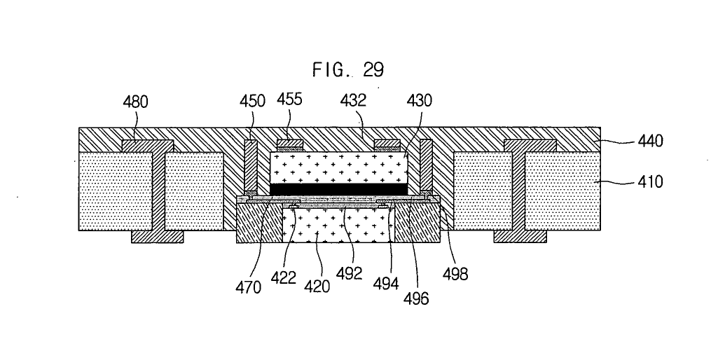

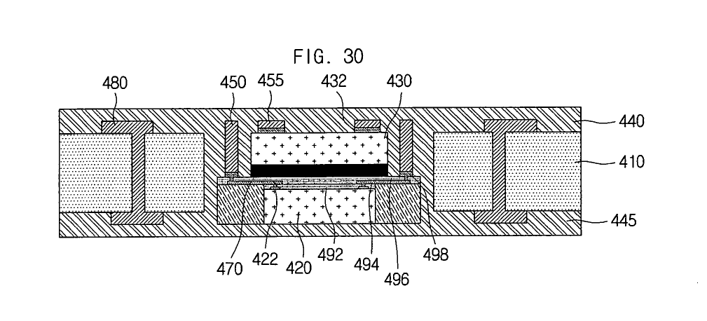

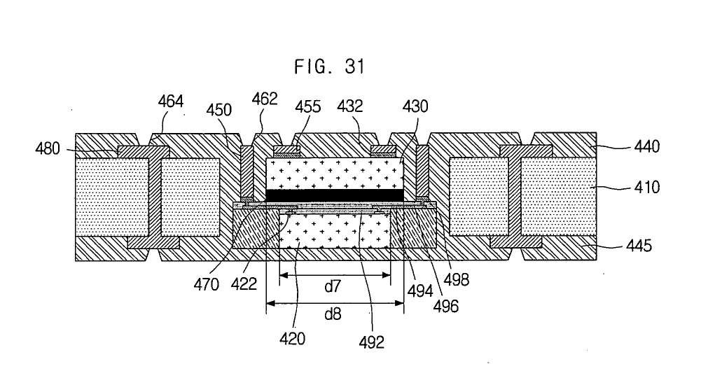

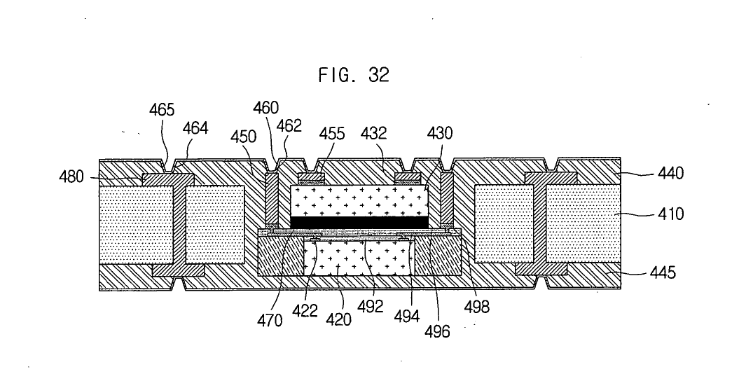

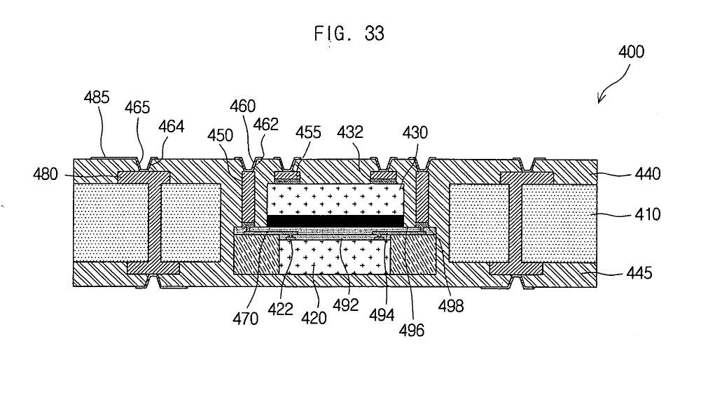

FIG. 18 is a flowchart illustrating a second disclosed embodiment of a method for manufacturing a PCB having embedded components according to another aspect of the present invention, and FIG. 19 to FIG. 33 are cross-sectional views illustrating each process in the second disclosed embodiment of a method for manufacturing a PCB having embedded components according to another aspect of the present invention.

In FIG. 18 to FIG. 33 are illustrated a component-embedded PCB 400, a dielectric substrate 410, a cavity 415, a first component 420, a second component 430, electrodes 422, 432, a first dielectric layer 440, a second dielectric layer 445, first metal posts 450, second metal posts 455, via holes 462, 464, vias 460, 465, an adhesive layer 470, a first circuit pattern 480, a second circuit pattern 485, a securing tape 475, a redistribution layer 494, a first protection layer 492, a second protection layer 496, and bumps 498.

According to this embodiment, a method for manufacturing a PCB 400 having embedded components is presented, in which a redistribution layer 494 is formed, so that the design of the PCB 400 is not limited by the widths d7, d8 of the first component 420 and second component 430, for an increased degree of freedom in design.

Operation S32 of FIG. 18 may include forming a first circuit pattern 480 on one side or both sides of a dielectric substrate 410, where FIG. 19 represents a corresponding process.

Operation S34 of FIG. 18 may include forming a cavity 415 in one side of the dielectric substrate 410, where FIG. 20 represents a corresponding process.

Operation S36 of FIG. 18 may include applying a securing tape 475 on the other side of the dielectric substrate 410 so as to fix a first component 420 in the cavity 415, where FIG. 21 represents a corresponding process.

Operation S38 of FIG. 18 may include forming a redistribution layer 494, where FIG. 22 represents a corresponding process.

Operation S40 of FIG. 18 may include forming first metal posts 450 that are electrically connected with the first component 420 on the electrodes 422 of the first component 420, where FIG. 23 represents a corresponding process.

Operation S42 of FIG. 18 may include inserting the first component 420 in the cavity 415 such that the electrodes face one side of the dielectric substrate 410, where FIG. 24 represents a corresponding process.

Operation S44 of FIG. 18 may include forming an adhesive layer 470 on one side of the first component 420, where FIG. 25 represents a corresponding process.

Operation S46 of FIG. 18 may include forming second metal posts 455 that are electrically connected with a second component 430 on the electrodes 432 of the second component 430, where FIG. 26 represents a corresponding process.

Operation S48 of FIG. 18 may include mounting the second component 430 on one side of the first component 420 such that the electrodes 432 face the same direction as the electrodes 422 of the first component 420, where FIG. 27 represents a corresponding process.

Operation S50 of FIG. 18 may include forming a first dielectric layer 440 on one side of the dielectric substrate 410, where FIG. 28 represents a corresponding process.

Operation S52 of FIG. 18 may include removing the securing tape 475, where FIG. 29 represents a corresponding process.

Operation S54 of FIG. 18 may include forming a second dielectric layer 445 on the other side of the dielectric substrate 410, where FIG. 30 represents a corresponding process.

Operation S56 of FIG. 18 may include forming vias 460 on one side of the first dielectric layer 440 that are connected electrically to the first metal posts 450 and second metal posts 455 respectively, where FIG. 31 and FIG. 32 represent corresponding processes.

Operation S58 of FIG. 18 may include forming a second circuit pattern 485 on one side of the first dielectric layer 440 and/or one side of the second dielectric layer 445, where FIG. 33 represents a corresponding process.

In this embodiment, forming the first circuit pattern 480, forming the cavity 415 in the dielectric substrate 410, applying the securing tape 475, forming the first metal posts 450, inserting the first component 420, forming the adhesive layer 470, forming the second metal posts 455, mounting the second component 430, forming the first dielectric layer 440, removing the securing tape 475, forming the second dielectric layer 445, forming the vias 460, 465 by perforating via holes 462, 464, and forming the second circuit pattern 485 are the same or are in correspondence with the operations described above with reference to the first disclosed embodiment of a method for manufacturing a component-embedded PCB according to another aspect of the present invention. Thus, redundant explanations will be omitted, and the following will focus on descriptions on forming the redistribution layer 294, which is a difference from the first disclosed embodiment of the method for manufacturing a component-embedded PCB.

Operation S38 of FIG. 18 may include forming a redistribution layer 494 on one side of the first component 420 such that is connected electrically with an electrode 422 of the first component 420. FIG. 22 represents a corresponding process.

First, a first protection layer 492 may be formed on one side of the first component 420, with portions of the electrodes 422 of the first component 420 exposed. That is, the first protection layer 492 may be formed by a process of exposure and development according to photolithography, and the first protection layer 492 may serve as the base of the redistribution layer 494.

Next, the redistribution layer 494 may be formed between the first component 420 and the second component 430, such that the redistribution layer 494 is connected electrically with an electrode 422 of the first component 420. That is, a molding material may be formed on the side of the first component 420 that may be used as the base of the redistribution layer 494, after which the redistribution layer 494, which is electrically connected with an electrode 422 of the first component 420, may be formed on one side of the molding material and the first protection layer 492.

The redistribution layer 494 may be formed by forming a plating layer on one side of molding material and the first protection layer 492, for example, by plating, and forming an etching resist layer on which a pattern may be formed by a method of photolithography, and finally selectively etching the plating layer.

Next, a second protection layer 496 may be formed on one side of the first protection layer 492, with portions of the redistribution layer 494 exposed where the first metal posts 450 are to be formed. Similar to the first protection layer 492, the second protection layer 496 may be formed by photolithography.

Lastly, a bump 498 may be formed on a portion of the redistribution layer 494 exposed so that the first metal post 450 may be formed easily. Similar to the redistribution layer 494, the bumps 498 may be formed by forming a plating layer, for example, by plating, and forming an etching resist layer on which a pattern may be formed by a method of photolithography, and finally selectively etching the plating layer.

According to this embodiment, a component-embedded PCB 400 can be manufactured more easily with an increased degree of freedom in design, as a redistribution layer 494 may be interposed between the first component 420 and second component 430, so that the first metal posts 450 and second metal posts 455 may be formed without being limited by the widths d7, d8 of the first component 420 and second component 430, even when the width d7 of the first component 420 is smaller than the width d8 of the second component 430.

According to certain aspects of the invention as set forth above, a first component and a second component having different thicknesses may be mounted sequentially or collectively, and vias for electrical connection to the exterior may be formed more easily.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method for manufacturing a printed circuit board having embedded components, the method comprising:
forming a cavity in one side of a dielectric substrate;
inserting a first component in the cavity such that an electrode thereof faces the one side of the dielectric substrate;
mounting a second component on one side of the first component such that an electrode thereof faces the same direction as the electrode of the first component;
forming a first dielectric layer on one side of the dielectric substrate such that the first dielectric layer covers the second component; and
forming a second dielectric layer on the other side of the dielectric substrate such that the second dielectric layer covers the first component.

2. The method of claim 1, further comprising, before forming the first dielectric layer and the second dielectric layer:
forming a first circuit pattern on at least one side of the dielectric substrate.

3. The method of claim 1, further comprising, before inserting the first component:
applying a securing tape on the other side of the dielectric substrate such that the first component is secured in the cavity,
and further comprising, after forming the first dielectric layer:
removing the securing tape.

4. The method of claim 1, further comprising, before forming the first dielectric layer:
forming a first metal post on an electrode of the first component such that the first metal post is connected electrically with the first component; and
forming a second metal post on an electrode of the second component such that the second metal post is connected electrically with the second component.

5. The method of claim 4, further comprising, after forming the first dielectric layer:
forming vias on one side of the first dielectric layer such that the vias are connected electrically to the first metal post and the second metal post respectively.

6. The method of claim 1, further comprising, before mounting the second component:
forming an adhesive layer on one side of the first component.

7. The method of claim 1, further comprising, after forming the first dielectric layer and forming the second dielectric layer:
forming a second circuit pattern on at least one of one side of the first dielectric layer and one side of the second dielectric layer.

8. The method of claim 1, wherein a width of the first component is greater than a width of the second component.

9. The method of claim 1, wherein a thickness of the first component is greater than a thickness of the second component.

10. The method of claim 1, wherein mounting the second component is performed before inserting the first component.

11. The method of claim 1, wherein forming the second dielectric layer is performed before inserting the first component.

12. The method of claim 1, further comprising, before mounting the second component:
forming a redistribution layer on one side of the first component such that the redistribution layer is connected electrically with an electrode of the first component.
